(19) United States
(12) Patent Application Publication
(10) Pub. No.: US 2015/0207064 A1
(43) Pub. Date: Jul. 23, 2015

(54) METHODS OF MANUFACTURING MAGNETORESISTIVE RANDOM ACCESS MEMORY DEVICES

(71) Applicants: Joon-Myoung LEE, Suwon-si (KR); Hong-Lae PARK, Seongnam-si (KR); Sang-Yong KIM, Suwon-si (KR); Woo-Chang LIM, Gwanak-gu (KR)

(72) Inventors: Joon-Myoung LEE, Suwon-si (KR); Hong-Lae PARK, Seongnam-si (KR); Sang-Yong KIM, Suwon-si (KR); Woo-Chang LIM, Gwanak-gu (KR)

(21) Appl. No.: 14/505,995

(22) Filed: Oct. 3, 2014

(30) Foreign Application Priority Data
Jan. 17, 2014 (KR) 10-2014-0005869

(51) Int. Cl. H01L 43/12; H01L 43/10

(52) U.S. Cl. CPC H01L 43/12; H01L 43/10

(57) ABSTRACT

A MRAM device may include a fixed layer pattern on a substrate, a first tunnel barrier layer pattern on the fixed layer pattern, a free layer pattern on the first tunnel barrier layer pattern, a second tunnel barrier layer pattern on the free layer pattern, the second tunnel barrier layer pattern including a metal oxide, and a capping layer pattern on the second tunnel barrier layer pattern. The capping layer pattern including a metal may have an oxide layer formation energy lower than the oxide layer formation energy of tantalum.

### CROSS-REFERENCE TO RELATED APPLICATION

This application claims priority under 35 USC §119 from Korean Patent Application No. 10-2014-0005869, filed on Jan. 17, 2014 in the Korean Intellectual Property Office (KIPO), the contents of which are herein incorporated by reference in their entirety.

### BACKGROUND

1. Field

Example embodiments relate to magnetoresistive random access memory (MRAM) devices and methods of manufacturing the same.

2. Description of the Related Art

An MRAM device may include a plurality of magnetic tunnel junction (MTJ) structures in which a fixed layer pattern, a first tunnel barrier layer pattern, a free layer pattern and a second tunnel barrier layer pattern may be sequentially stacked. In a method of manufacturing the MRAM device, a high temperature process may be performed in order to form a metal wiring and/or to improve a crystal property of the free layer pattern. Thus, the crystal property of the free layer pattern may be deteriorated so that a tunneling magneto resistance (TMR) may be decreased.

### SUMMARY

Example embodiments provide an MRAM device having good characteristics.

Example embodiments provide a method of manufacturing an MRAM device having good characteristics.

According to example embodiments, there is provided an MRAM device. The MRAM device may include a fixed layer pattern on a substrate, a first tunnel barrier layer pattern on the fixed layer pattern, a free layer pattern on the first tunnel barrier layer pattern, a second tunnel barrier layer pattern on the free layer pattern, the second tunnel barrier layer pattern including a metal oxide and a capping layer pattern on the second tunnel barrier layer pattern. The capping layer pattern may include a metal having an oxide layer formation energy lower than the oxide layer formation energy of tantalum.

In example embodiments, the capping layer pattern may include at least one of magnesium, hafnium, aluminum, titanium, beryllium, terbium and zirconium.

In example embodiments, the capping layer pattern may include a metal having a melting temperature that is higher than the melting temperature of aluminum.

In example embodiments, the capping layer pattern may include magnesium.

In example embodiments, the capping layer pattern may absorb oxygen generated from the second tunnel barrier layer pattern

In example embodiments, the capping layer pattern may absorb oxygen generated from the second tunnel barrier layer pattern when an annealing process is performed at a temperature of more than about 300° C.

In example embodiments, the first and second tunnel barrier layer patterns may include magnesium oxide.

In example embodiments, the free layer pattern may include CoFeB.

In example embodiments, the MRAM device may further include an upper electrode electrically connected to the capping layer pattern, a bit line electrically connected to the upper electrode, a transistor electrically connected to the lower electrode and a source line electrically connected to the transistor.

According to example embodiments, there is provided a method of manufacturing an MRAM device. A lower electrode layer, a fixed layer, a first tunnel barrier layer and a free layer may be sequentially formed on a substrate. A second tunnel barrier layer including a metal oxide may be formed on the free layer. A capping layer including a metal having an oxide layer formation energy lower than the oxide layer formation energy of tantalum may be formed on the second tunnel barrier layer. An upper electrode layer may be formed on the capping layer. The upper electrode layer may be patterned to form an upper electrode. The capping layer, the second tunnel barrier layer, the free layer, the first tunnel barrier layer, the fixed layer and the lower electrode layer may be sequentially patterned using the upper electrode as an etching mask to form a capping layer pattern, a second tunnel barrier layer pattern, a free layer pattern, a first tunnel barrier layer pattern, a fixed layer pattern and a lower electrode, respectively.

In example embodiments, the capping layer pattern may include magnesium.

In example embodiments, after forming the capping layer pattern, an upper electrode may be formed on the capping layer pattern. A wiring may be formed on the upper electrode, wherein forming the wiring is performed at a temperature of more than about 350° C.

In example embodiments, the second tunnel barrier layer may be formed using magnesium oxide.

In example embodiments, the first tunnel barrier layer may be formed using magnesium oxide.

In example embodiments, the free layer pattern is formed using CoFeB.

According to example embodiments, an MTJ structure may include a capping layer pattern containing a metal having a high absorption of oxygen so that a movement of oxygen excessively generated from a second tunnel barrier layer pattern beneath the capping layer may be suppressed. Thus, the MTJ structure may maintain a high TMR.

### BRIEF DESCRIPTION OF THE DRAWINGS

Example embodiments will be more clearly understood from the following detailed description taken in conjunction with the accompanying drawings. FIGS. 1 to 26 represent non-limiting, example embodiments as described herein.

FIG. 1 is a cross-sectional view illustrating a magnetic tunnel junction (MTJ) structure in accordance with example embodiments;

FIG. 2 is a cross-sectional view illustrating an MTJ structure in accordance with Comparative Example;

FIGS. 3 to 5 are cross-sectional views illustrating stages of a method of manufacturing an MTJ structure in accordance with example embodiments;

FIGS. 6 to 26 are cross-sectional views illustrating stages of a method of manufacturing an MRAM device in accordance with example embodiments; and

FIG. 27 is a flow chart illustrating a method of manufacturing an MRAM device in accordance with example embodiments.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain example embodiments of the present description.

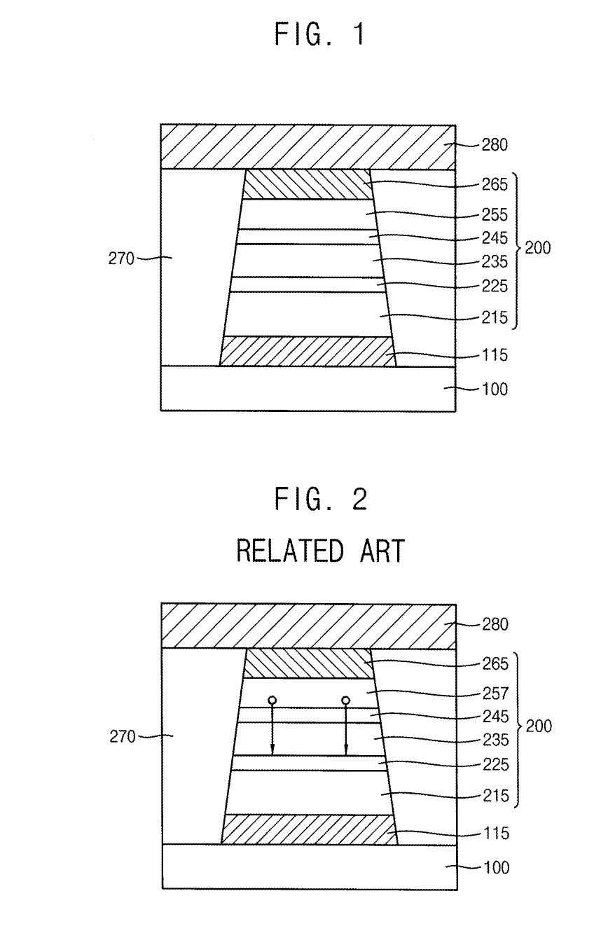

FIG. 1 is a cross-sectional view illustrating a magnetic tunnel junction (MTJ) structure in accordance with example embodiments, and FIG. 2 is a cross-sectional view illustrating an MTJ structure in accordance with Comparative Example.

Referring to FIG. 1, an MTJ structure 200 may include a fixed layer pattern 215, a first tunnel barrier layer pattern 225, a free layer pattern 235, a second tunnel barrier layer pattern 245 and a capping layer pattern 255 sequentially stacked on a substrate 100. A lower electrode 115 and an upper electrode 265 may be formed beneath and on the MTJ structure 200, respectively. A wiring 280 may be formed on an insulating interlayer 270 covering the MTJ structure 200, the lower electrode 115 and the upper electrode 265, and may be electrically connected to the upper electrode 265.

The fixed layer pattern 215 may include a ferromagnetic material, e.g., CoFeB, CoFe, NiFe, etc. The fixed layer pattern 215 may have a first magnetization direction fixed in one direction. In example embodiments, the first magnetization direction may be substantially perpendicular to a top surface of the substrate 100 or substantially parallel to the top surface of the substrate 100.

The free layer pattern 235 may include a ferromagnetic material, e.g., CoFeB. The free layer pattern 235 may have a second magnetization direction which may not be fixed in one direction but may be reversible. In example embodiments, the second magnetization direction may be substantially perpendicular or parallel to the top surface of the substrate 100. In an example embodiment, the second magnetization direction may be substantially the same as the first magnetization direction.

The first and second tunnel barrier layer patterns 225 and 245 may include a metal oxide, e.g., magnesium oxide (MgO) or aluminum oxide (AlOx), a metal nitride, or a metal oxynitride.

The capping layer pattern 255 may include a metal having an oxide layer formation energy lower than the oxide layer formation energy of tantalum (Ta) such as e.g., magnesium (Mg), hafnium (Hf), aluminum (Al), titanium (Ti), beryllium (Be), terbium (Db), zirconium (Zr), etc. That is, the metal of the capping layer pattern 255 may have a high absorption of oxygen so that a movement of oxygen excessively generated from an underlying layer may be reduced or suppressed when compared to the capping layer pattern including, e.g., Ta. The capping layer pattern 255 may also include a metal having a melting temperature that is higher than the melting temperature of Al, e.g., Ti, Mg, Hf, etc. In example embodiments, the capping layer pattern 255 may include a metal having an oxide layer formation energy lower than the oxide layer formation energy of Ta and a melting temperature that is higher than the melting temperature of Al. A protection layer (not shown) may be formed on the capping layer pattern 255, which may include a metal, e.g., Ta.

The lower and upper electrodes 115 and 265 may include a conductive material containing a metal and/or a metal nitride, e.g., tungsten (W), Ti, tungsten nitride (WN), titanium nitride (TiN), tantalum nitride (TaN), etc. In an example embodiment, the lower and upper electrodes 115 and 265 may include substantially the same material.

The insulating interlayer 270 may include an oxide, e.g., silicon oxide, and the wiring 280 may include a metal, a metal nitride and/or a metal silicide, e.g., W, Al, copper (Cu), etc. In example embodiments, a plurality of wirings 280 may be formed.

The composition of the MTJ structure 200 may not be limited to the above, and may be varied.

The MTJ structure 200 may be exposed to a high temperature process after the formation thereof. For example, an annealing process for the MTJ structure 200 may be performed at a high temperature of more than about 350° C., which may be performed to improve a crystal property of the free layer pattern 235 and/or to form the wiring 280 on the MTJ structure 200. During the annealing process, oxygen may be excessively generated from the second tunnel barrier layer pattern 245, and the excessive oxygen may move toward an interface between the free layer pattern 235 and the first tunnel barrier layer pattern 225. The capping layer pattern 255, in accordance with example embodiments, however, may include the metal having an oxide layer formation energy lower than the oxide layer formation energy of Ta such as e.g., Mg, and thus, the excessive oxygen generated from the second tunnel barrier layer pattern 245 may be effectively absorbed into the capping layer pattern 255. The excessive oxygen generated from the second tunnel barrier layer pattern 245 may not move toward the interface between the free layer pattern 235 and the first tunnel barrier layer pattern 225 so that the crystal property of the free layer pattern 235 may be substantially prevented from being deteriorated, or the deterioration of the crystal property of the free layer pattern 235 may be reduced. Thus, a TMR of the MTJ structure 200 may be maintained at a substantially high value. The capping layer pattern 255 may include a metal having a melting temperature that is higher than the melting temperature of Al such as e.g., Mg so that the capping layer pattern 255 may protect the second tunnel barrier layer pattern 245 and the free layer pattern 235 therebeneath from other structures in the MTJ structure 200 without affecting them.

On the other hand, a MTJ structure 205 in FIG. 2 may not have a high TMR, which may be different from the TMR of the MTJ structure 200 in FIG. 1.

Referring to FIG. 2, which illustrates a comparative example, the MTJ structure 205 may include a fixed layer pattern 215, a first tunnel barrier layer pattern 225, a free layer pattern 235, a second tunnel barrier layer pattern 245 and a capping layer pattern 257 on a substrate 100. The capping layer pattern 257 may include, e.g., Ta.

In this Comparative Example, when the MTJ structure 205 is exposed to a high temperature, e.g., of more than about 300° C., oxygen excessively generated from the second tunnel barrier layer pattern 245 may not be effectively removed because Ta in the capping layer pattern 257 may not effectively absorb the excessive oxygen. An oxygen layer formation energy of Ta in the capping layer pattern 257 of the Comparative Example may be higher than the oxide layer formation energy in the capping layer pattern 255 of the example embodiments, and thus, the excessive oxygen may not be effectively absorbed into the capping layer pattern 257, and move toward an interface between the free layer pattern 235 and the first tunnel barrier layer pattern 225. Thus, a crystal property of the free layer pattern 235 may be deteriorated. Therefore, the MTJ structure 205 of the Comparative Example may not have a high TMR.

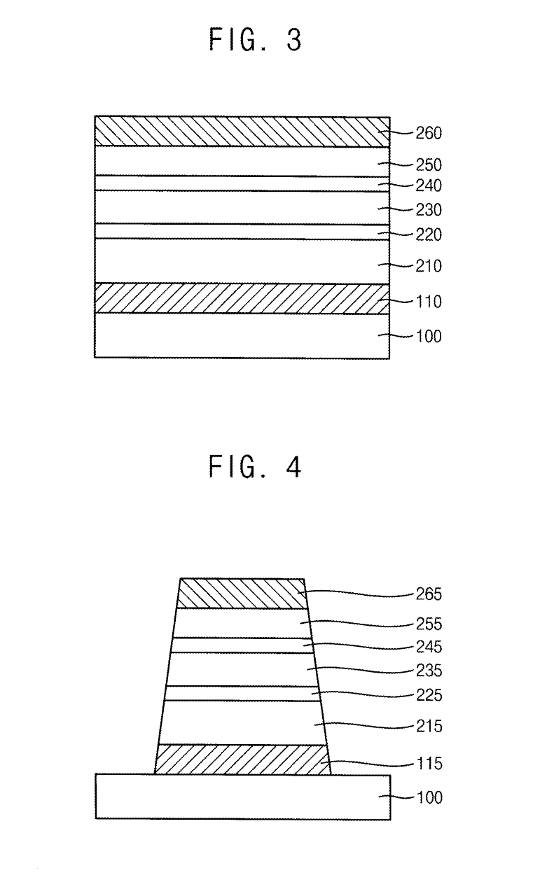

FIGS. 3 to 5 are cross-sectional views illustrating stages of a method of manufacturing a MTJ structure in accordance with example embodiments.

Referring to FIG. 3, a lower electrode layer 110, a fixed layer 210, a first tunnel barrier layer 220, a free layer 230, a second tunnel barrier layer 240, a capping layer 250 and an upper electrode layer 260 may be sequentially stacked on a substrate 100.

The substrate 100 may be a silicon substrate, a germanium substrate, a silicon-germanium substrate, a silicon-on-insulator (SOI) substrate, a germanium-on-insulator (GOI) substrate, etc.

The fixed layer 210 may be formed to include a ferromagnetic material, e.g., CoFeB, CoFe, NiFe, etc. The free layer 230 may be formed to include a ferromagnetic material, e.g., CoFeB. The first and second tunnel barrier layers 220 and 240 may be formed to include a metal oxide, e.g., magnesium oxide (MgO) or aluminum oxide (AlOx), a metal nitride, or a metal oxynitride. The capping layer 250 may be formed to include a metal having an oxide layer formation energy that is lower than the oxide layer formation energy of tantalum (Ta) such as, e.g., magnesium (Mg), hafnium (Hf), aluminum (Al), titanium (Ti), beryllium (Be), terbium (Db), zirconium (Zr), etc. The capping layer 250 may be also formed to include a metal having a melting temperature that is higher than the melting temperature of Al such as, e.g., Ti, Mg, Hf, etc. In example embodiments, the capping layer 250 may be formed to include a metal having an oxide layer formation energy that is lower than the oxide layer formation energy of Ta, and a melting temperature that is higher than the melting temperature of Al. A protection layer (not shown) may be formed on the capping layer 250, which may include a metal such as, e.g., Ta.

The lower and upper electrode layers 110 and 260 may be formed to include a conductive material containing a metal, e.g., W, Ti and/or a metal nitride, e.g., WN, TiN, TaN, etc.

Referring to FIG. 4, the upper electrode layer 260 may be partially etched to form an upper electrode 265, and the upper electrode 265 may be used as an etching mask to form a MTJ structure 200.

Particularly, the upper electrode layer 260 may be patterned to form the upper electrode 265, and the capping layer 250, the second tunnel barrier layer 240, the free layer 230, the first tunnel barrier layer 220, the fixed layer 210 and the lower electrode layer 110 may be sequentially etched using the upper electrode 265 as the etching mask. Thus, the MTJ structure 200 may be formed to include a fixed layer pattern 215, a first tunnel barrier layer pattern 225, a free layer pattern 235, a second tunnel barrier layer pattern 245 and a capping layer pattern 255 sequentially stacked on a lower electrode 115.

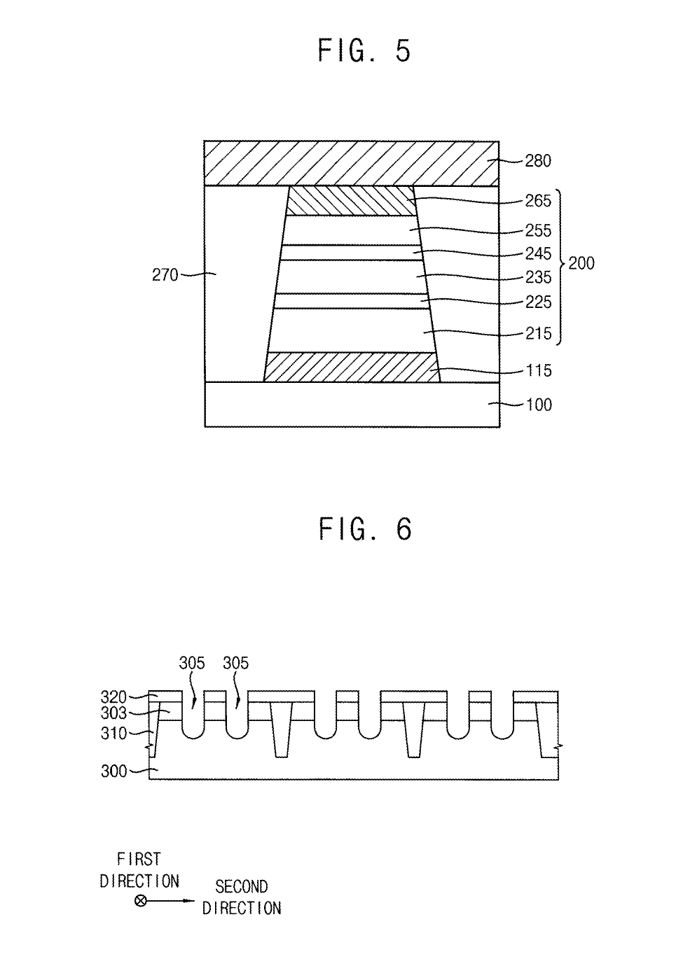

Referring to FIG. 5, an insulating interlayer 270 may be formed to cover the lower electrode 115, the MTJ structure 200 and the upper electrode 265, and a wiring 280 may be formed on the insulating interlayer 270.

The insulating interlayer 270 may be formed using an oxide, e.g., silicon oxide, and the wiring 280 may be formed using a metal such as, e.g., W, Al, copper (Cu), a metal nitride, a metal silicide, etc., at a high temperature. For example, the process for forming the wiring forming the wiring 280 may be performed at a temperature of more than about 300° C. In example embodiments, a plurality of wirings 280 may be formed.

The capping layer pattern 255 of the MTJ structure 200, in accordance with example embodiments, may absorb oxygen excessively generated from the second tunnel barrier layer pattern 245 when the process is performed at a high temperature. Thus, the excessive oxygen generated from the second tunnel barrier layer pattern 245 may not move to an interface between the free layer pattern 235 and the first tunnel barrier layer pattern 225 so that a high TMR of the MTJ structure 200 may be maintained.

FIGS. 6 to 26 are cross-sectional views illustrating stages of a method of manufacturing a MRAM device in accordance with example embodiments.

Referring to FIG. 6, impurities may be implanted into an upper portion of a substrate 300 to form an impurity region 303, and an isolation layer pattern 310 may be formed on the substrate 300. Accordingly, a portion of the substrate 300 on which the isolation layer pattern 310 is formed may be defined as a field region, a portion of the substrate 300 on which no isolation layer pattern is formed may be defined as an active region, and thus the substrate 300 may be divided into the active region and the field region.

The substrate 300 may be a silicon substrate, a germanium substrate, a silicon-germanium substrate, a silicon-on-insulator (SOI) substrate, a germanium-on-insulator (GOI) substrate, etc.

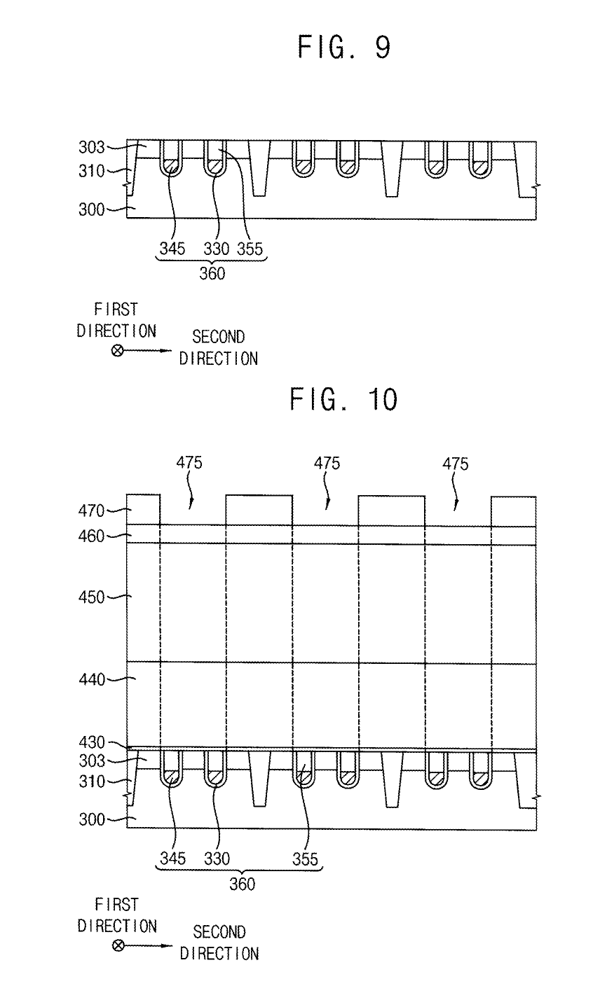

The impurity region 303 may be formed by performing an ion implantation process on the substrate 300, and may include, e.g., n-type impurities such as phosphorus, arsenic, etc., or p-type impurities such as boron, gallium, etc. The impurity region 303 together with a gate structure 360 subsequently formed (refer to FIG. 9) may be defined as a transistor, and the impurity region 303 may serve as source/drain regions of the transistor.

The isolation layer pattern 310 may be formed by forming a first trench (not shown) at an upper portion of the substrate 300, forming an isolation layer on the substrate 300 to sufficiently fill the first trench, and planarizing an upper portion of the isolation layer until a top surface of the substrate 300 may be exposed. The isolation layer may be formed to include an oxide, for example, silicon oxide.

In example embodiments, the impurity region 303 may be formed after the isolation layer pattern 310 is formed.

A first mask 320 may be formed on the substrate 300 to expose a portion of the substrate 300, and the exposed portion of the substrate 300 may be removed using the first mask 320 as an etching mask to form a second trench 305.

In example embodiments, a plurality of second trenches 305 may be formed in a second direction substantially parallel to the top surface of the substrate 300, each of which may extend in a first direction substantially parallel to the top surface of the substrate 300 and substantially perpendicular to the second direction. In example embodiments, two second trenches 305 may be formed within each active region divided by the isolation layer pattern 310.

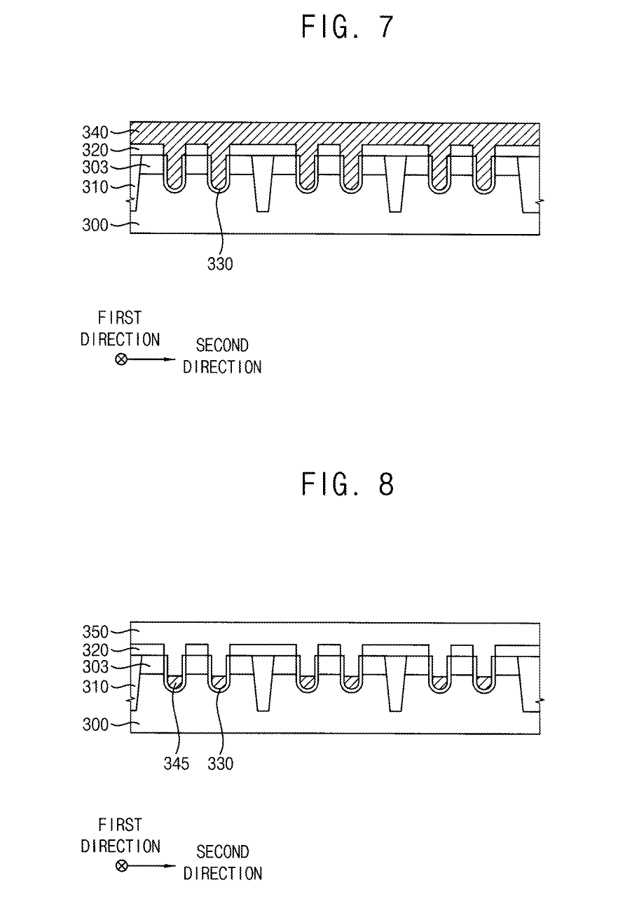

Referring to FIG. 7, a gate insulation layer 330 may be formed on an inner wall of the second trench 305, and a gate electrode layer 340 may be formed on the gate insulation layer 330 and the first mask 320 to sufficiently fill the second trench 305.

In example embodiments, the gate insulation layer 330 may be formed by performing a thermal oxidation process or a chemical vapor deposition (CVD) process on an upper portion of the substrate 300 exposed by the second trench 305. The gate insulation layer 330 may be formed to include an oxide, e.g., silicon oxide.

The gate electrode layer 340 may be formed to include a metal such as tungsten (W), titanium (Ti), tantalum (Ta), etc., a metal nitride such as tungsten nitride (WN), titanium nitride (TiN), tantalum nitride (TaN), etc., and/or a metal silicide.

Referring to FIG. 8, an upper portion of the gate electrode layer 340 may be removed to form a gate electrode 345 partially filling the second trench 305, and a first capping layer 350 may be formed on the gate electrode 345, the gate insulation layer 330 and the first mask 320 to fill a remaining portion of the second trench 305.

In example embodiments, the gate electrode layer 340 may be removed by a chemical mechanical polishing (CMP) process and/or an etch back process. Accordingly, the gate electrode 345 may be formed in a lower portion of the second trench 305 to extend in the first direction, and a plurality of gate electrodes 345 may be formed in the second direction. In an example embodiment, when the gate electrode 345 is formed, a portion of the gate insulation layer 330 may be removed, and thus the gate insulation layer 330 may be formed on a lower inner wall of the second trench 305 to surround a sidewall and a bottom surface of the gate electrode 345.

The first capping layer 350 may be formed to include a nitride, e.g., silicon nitride.

Referring to FIG. 9, an upper portion of the first capping layer 350 and the first mask 320 may be removed by, e.g., a CMP process until the top surface of the substrate 300 may be exposed. Accordingly, a first capping layer pattern 355 may be formed to fill an upper portion of the second trench 305. In example embodiments, a plurality of first capping layer patterns 355 may be formed in the second direction, each of which may extend in the first direction.

The gate insulation layer 330, the gate electrode 345 and the first capping layer pattern 355 may form a gate structure 360. That is, the gate structure 360 may be a buried gate structure filling the second trench 305. In example embodiments, a plurality of gate structures 360 may be formed in the second direction, each of which may extend in the first direction. In example embodiments, two gate structures 360 may be formed within each active region.

Referring to FIG. 10, an etch stop layer 430, a first insulating interlayer 440, a silicon-on-hardmask (SOH) layer 450, a silicon oxynitride layer 460 and a first photoresist pattern 470 may be sequentially formed on the substrate 300.

The etch stop layer 430 may be formed to include a nitride, e.g., silicon nitride, and the first insulating interlayer 440 may be formed to include an oxide, e.g., boro-phospho-silicate glass (BPSG), undoped silicate glass (USG), spin on glass (SOG), etc. A portion of the first insulating interlayer 440 may be removed in a subsequent processes, and thus may serve as a sacrificial layer.

The first photoresist pattern 470 may include first openings 475 exposing portions of a top surface of the silicon oxynitride layer 460. Each first opening 475 may extend in the first direction, and a plurality of first openings 475 may be formed in the second direction. In example embodiments, each first opening 475 may overlap two of the gate structures 360 adjacent to each other in each active region and a portion of the substrate 300 therebetween.

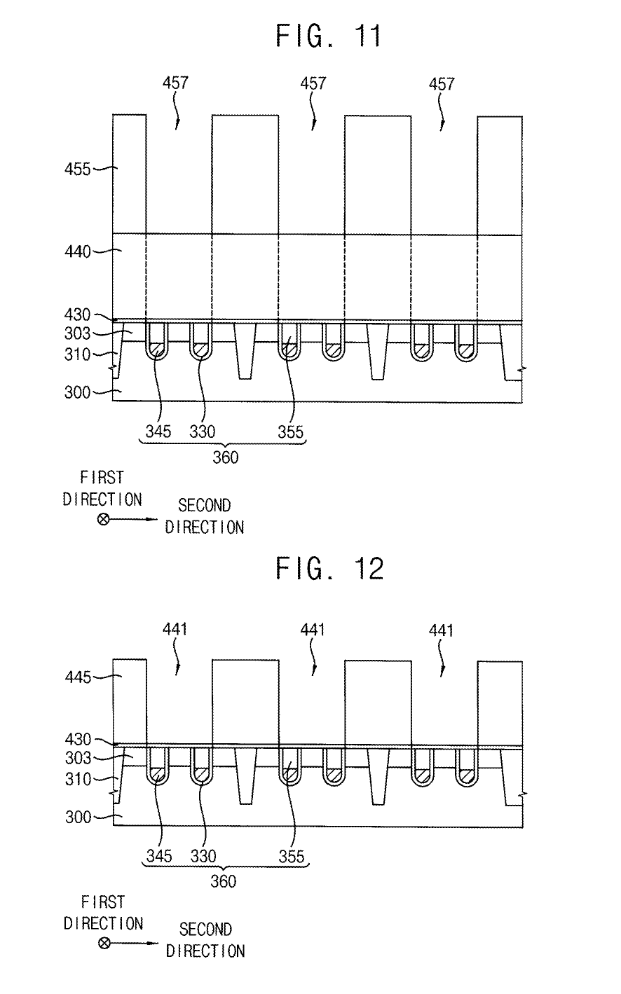

Referring to FIG. 11, the silicon oxynitride layer 460 and the SOH layer 450 may be sequentially etched using the first photoresist pattern 470 as an etching mask. Accordingly, a silicon oxynitride layer pattern and a SOH layer pattern 455 may be formed, and the SOH layer pattern 455 may include second openings 457 exposing portions of a top surface of the first insulating interlayer 440. The silicon oxynitride layer pattern may be removed by, e.g., a wet etching process after the SOH layer pattern 455 is formed.

Referring to FIG. 12, the first insulating interlayer 440 may be etched using the SOH layer pattern 455 as an etching mask. Accordingly, the exposed portions of the first insulating interlayer 440 may be removed to form a first insulating interlayer pattern 445 having third openings 441, and portions of a top surface of the etch stop layer 430 may be exposed.

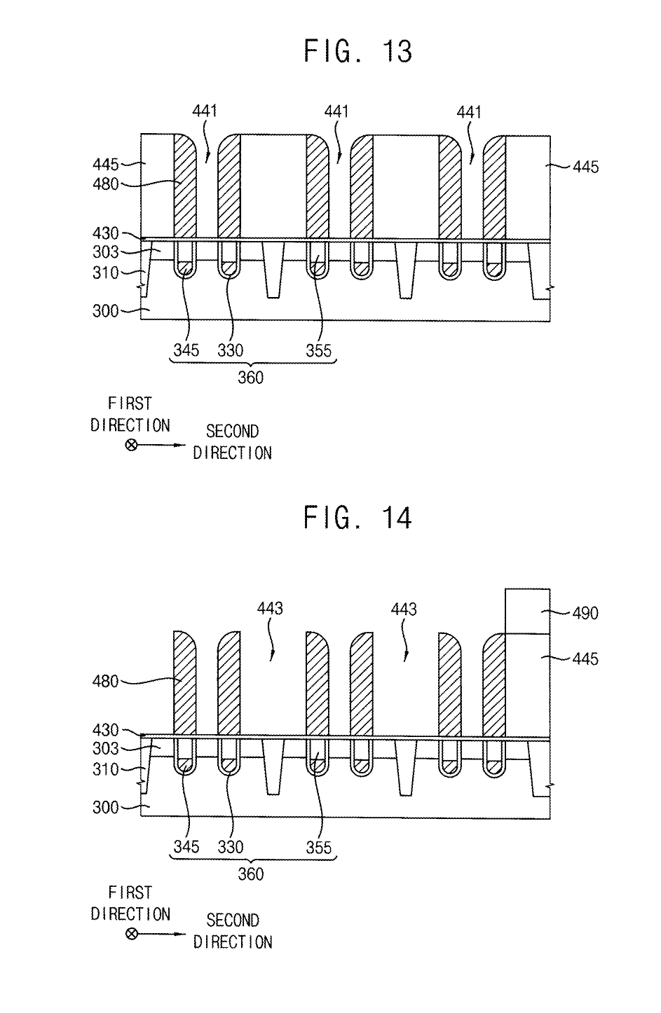

Referring to FIG. 13, a first spacer 480 may be formed on a sidewall of each third opening 441.

The first spacer 480 may be formed by forming a first spacer layer on the sidewalls of the third openings 441, the exposed portions of the etch stop layer 430 and a top surface of the first insulating interlayer pattern 445, and anisotropically etching the first spacer layer. Accordingly, two first spacers 480 may be formed on each active region, and each first spacer 480 may be formed to overlap the gate structure 360. In example embodiments, each third opening 441 may extend in the first direction, and a plurality of third openings 441 may be formed in the second direction. Thus, each first spacer 480 may extend in the first direction, and a plurality of first spacers 480 may be formed in the second direction. The first spacer layer may be formed to include a nitride, e.g., silicon nitride.

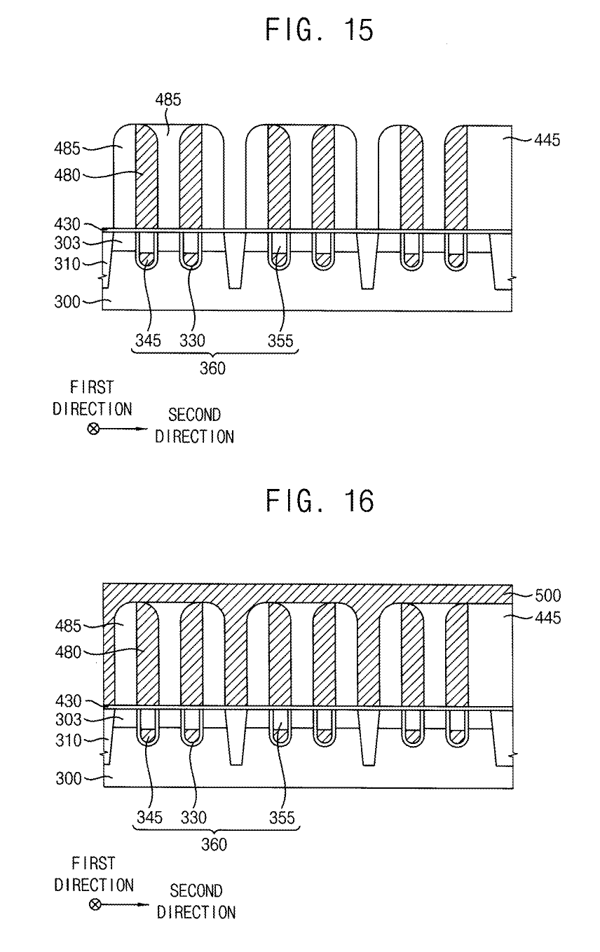

Referring to FIG. 14, a second mask 490 may be formed on a portion of the first insulating interlayer pattern 445, and exposed portions of the first insulating interlayer pattern 445 not covered by the second mask 490 may be removed to form fourth openings 443 exposing portions of a top surface of the etch stop layer 430.

The exposed portions of the first insulating interlayer pattern 445 may be removed by, e.g., a wet etching process.

The first spacers 480 may remain on the substrate 300, and may be spaced apart from each other in the second direction.

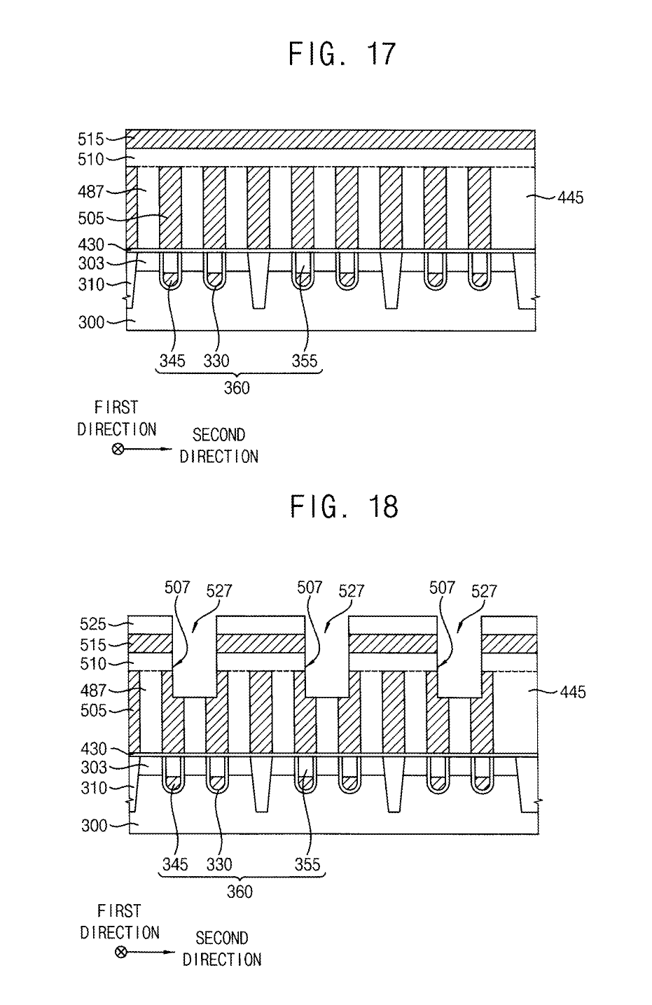

Referring to FIG. 15, the second mask 490 may be removed, and second spacers 485 contacting the first spacers 480 may be formed on the substrate 300.

In example embodiments, the second spacers 485 may be formed by forming a second spacer layer on the etch stop layer 430 and the first insulating interlayer pattern 445 to cover the first spacers 480, and anisotropically etching the second spacer layer. The second spacer layer may include an oxide, e.g., silicon oxide, and thus a portion of the second spacer layer contacting the first insulating interlayer pattern 445 may be merged thereto.

In example embodiments, the second spacers 485 may sufficiently fill spaces between two of the first spacers 480 which are spaced apart from each other in the second direction on each active region, and may partially fill spaces between two of the first spacers 480 adjacent to each other which define the fourth opening 443. That is, portions of the exposed top surface of the etch stop layer 430 by the fourth openings 443 may not be completely covered by the second spacers 485.

Referring to FIG. 16, a filling layer 500 may be formed on the etch stop layer 430, the first spacers 480, the second spacers 485 and the first insulating interlayer pattern 445 to fill remaining portions of the fourth openings 443.

In example embodiments, the filling layer 500 may be formed to include a material substantially the same as that of the second spacers 480, i.e., a nitride such as silicon nitride.

Referring to FIG. 17, an upper portion of the filling layer 500, upper portions of the first and second spacers 480 and 485, and an upper portion of the first insulating interlayer pattern 445 may be planarized to form first and second patterns 505 and 487, and second and third capping layers 510 and 515 may be sequentially formed.

In example embodiments, the planarization process may be performed by a CMP process and/or an etch back process.

According to the planarization process, the first spacers 480 and the filling layer 500 may be converted into the first patterns 505, and the second spacers 485 may be converted into the second patterns 487. Thus, each of the first and second patterns 505 and 487 may extend in the first direction, and the first and second patterns 505 and 487 may be alternately and repeatedly formed in the second direction. The first and second patterns 505 and 487 may contact each other. In example embodiments, at least some of the first patterns 505 may overlap the gate structure 360, and the others of the first patterns 505 may overlap the isolation layer pattern 310. In example embodiments, the second patterns 487 may overlap the impurity region 303 adjacent to the gate structure 360.

The second capping layer 510 may be formed to include an oxide, e.g., silicon oxide. The second capping layer 510 may cover top surfaces of the first and second patterns 505 and 487 and a top surface of the first insulating interlayer pattern 445, and may be merged to the second patterns 487 and the first insulating interlayer pattern 445.

The third capping layer 515 may be formed to include a nitride, e.g., silicon nitride.

Referring to FIG. 18, a second photoresist pattern 525 may be formed on the third capping layer 515, and the second and third capping layers 510 and 515 and upper portions of the first and second patterns 505 and 487 thereunder may be etched using the second photoresist pattern 525 as an etching mask to form recesses 507.

In example embodiments, the second photoresist pattern 525 may include fifth openings 527 exposing portions of a top surface of the third capping layer 515. In example embodiments, each fifth opening 527 may extend in the first direction, and a plurality of fifth openings 527 may be formed in the second direction. Each fifth opening 527 may overlap the second pattern 487 on a portion of the substrate 300 between the gate structures 360 adjacent to each other in each active region and a portion of the first patterns 505 adjacent thereto. Thus, the second patterns 487 on the substrate 300 between the gate structures 360 adjacent to each other in each active region may be exposed by the recesses 507.

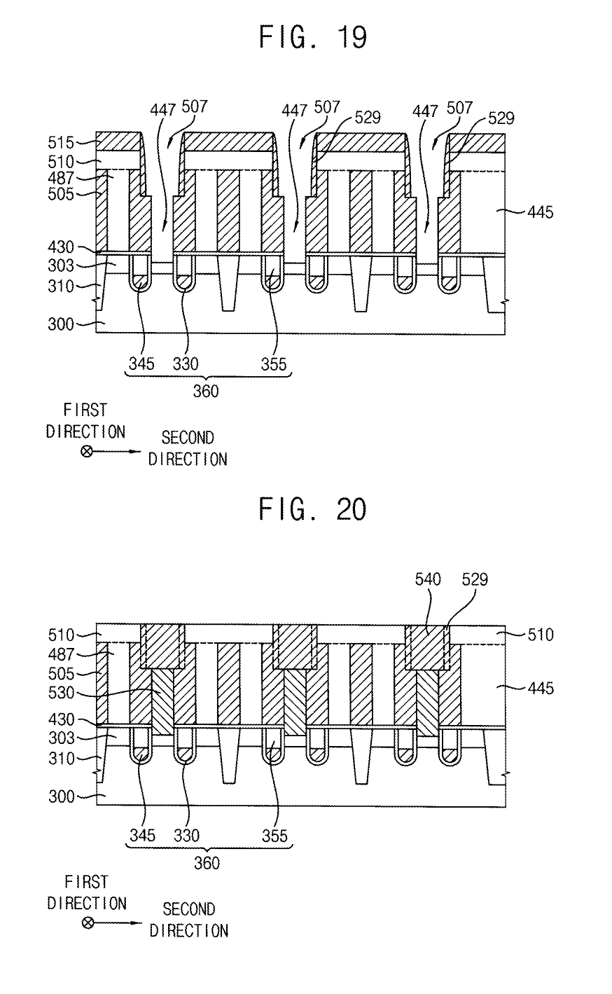

Referring to FIG. 19, the second photoresist pattern 525 may be removed, and an etch stop layer pattern 529 may be formed on sidewalls of the second and third capping layers 510 and 515 and upper sidewalls of the first patterns 505 exposed by each recess 507.

The etch stop layer pattern 529 may be formed by forming an etch stop layer on inner walls of the recesses 507 and the top surface of the third capping layer 515, and etching the etch stop layer anisotropically. Thus, the etch stop layer pattern 529 may cover sidewalls of the second and third capping layers 510 and 515.

The etch stop layer pattern 529 may be formed to include a material substantially the same as the material of the first patterns 505 and/or the third capping layer 515, i.e., a nitride such as silicon nitride to be merged thereto, and may have a high etching selectivity with respect to the second patterns 487 and/or the second capping layer 510. Accordingly, the second capping layer 510 may be substantially prevented from being etched by the etch stop layer pattern 529 when a wet etching process for the second patterns 487 is subsequently performed.

The second patterns 487 exposed by the recesses 507 may be removed, and portions of the etch stop layer 430 thereunder may be removed to form sixth openings 447 exposing upper portions of the substrate 300 and being in fluid communication with the recesses 507, respectively. The exposed second patterns 487 may be removed by, e.g., a wet etching process, and the portions of the etch stop layer 430 thereunder may be removed by, e.g., a dry etching process.

Each sixth opening 447 may be formed to extend in the first direction. The recess 507 and the sixth opening 447 in fluid communication therewith may be referred to simply as a seventh opening for the convenience of explanation.

Referring to FIG. 20, a source line 530 may be formed to fill each sixth opening 447, and a fourth capping layer pattern 540 may be formed on the source line 530 to fill each recess 507.

The source line 530 may be formed by forming a first conductive layer on the exposed upper portions of the substrate 300 to fill the sixth openings 447 and the recesses 507, and removing an upper portion of the first conductive layer. In example embodiments, portions of the first conductive layer in the recesses 507 may be removed. Accordingly, each source line 530 may extend in the first direction, and a plurality of source lines 530 may be formed in the second direction to fill lower portions of each seventh opening. The first conductive layer may be formed to include a metal, e.g., tungsten (W), titanium (Ti), tantalum (Ta), etc., and a metal nitride, e.g., tungsten nitride (WN), titanium nitride (TiN), tantalum nitride (TaN), etc.

The fourth capping layer pattern 540 may be formed by forming a fourth capping layer on the source lines 530, the etch stop layer patterns 529 and the third capping layer 515 to fill the recesses 507, and planarizing an upper portion of the fourth capping layer and the third capping layer 515 until a top surface of the second capping layer 510 may be exposed. Thus, the third capping layer 515 may be completely removed, and the fourth capping layer pattern 540 may fill the upper portions of the seventh openings. The fourth capping layer may be formed to include a nitride, e.g., silicon nitride, and thus the fourth capping layer pattern 540 may be merged to the first patterns 505 and/or the etch stop layer patterns 529.

Thereafter, a third mask (not shown) may be formed on the substrate 300, and the second capping layer 510 and the second patterns 487 may be etched using the third mask as an etching mask. In example embodiments, the etching process may be performed by, e.g., a dry etching process. During the dry etching process, portions of the etch stop layer 430 and the substrate 300 under the second patterns 487 may be also removed to form eighth openings (not shown) exposing upper portions of the substrate 300.

A first insulating layer (not shown) may be formed on the substrate 300, the first patterns 505, the fourth capping layer patterns 540 and the third mask to sufficiently fill the eighth openings, and an upper portion of the first insulating layer may be planarized until an upper portion of the third mask may be removed to form third patterns (not shown). The first insulating layer may include a nitride, e.g., silicon nitride, and thus may be merged to the first patterns 505, the fourth capping layer patterns 540, the etch stop layer patterns 529 and the second capping layer 510. In example embodiments, each third pattern may be formed to extend in the second direction, and a plurality of third patterns may be formed in the first direction.

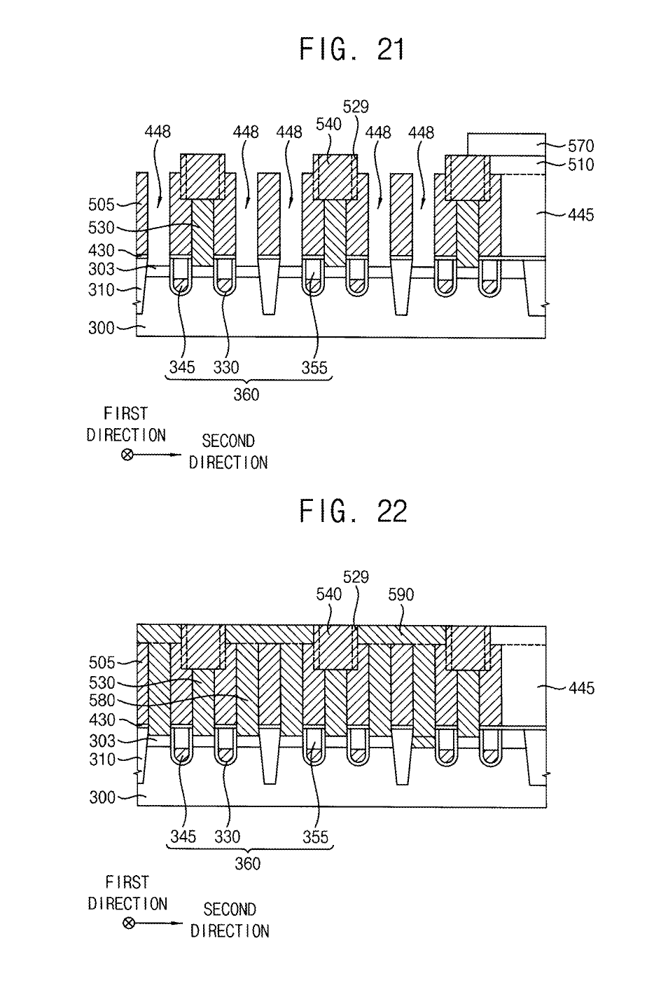

Referring to FIG. 21, a third photoresist pattern 570 may be formed on the second capping layer 510, portions of the fourth capping layer patterns 540 and the etch stop layer pattern 529 and the third patterns, and the second capping layer 510 and the second patterns 487 thereunder may be etched using the third photoresist pattern 570 as an etching mask.

In example embodiments, the second capping layer 510 and the second patterns 487 may include a material having an etching selectivity with respect to the first patterns 505, the third patterns, the fourth capping layer patterns 540 and the etch stop layer patterns 529, e.g., an oxide such as silicon oxide, and thus may be removed by performing a wet etching process.

Thereafter, portions of the etch stop layer 430 exposed by the etching process may be removed by a dry etching process to form ninth openings 448 exposing portions of the top surface of the substrate 300.

Referring to FIG. 22, the third photoresist pattern 570 may be removed by, e.g., a wet etching process, and a contact plug 580 and a pad layer 590 may be formed to fill each ninth opening 448.

The contact plug 580 and the pad layer 590 may be formed by forming a second conductive layer on the substrate 300, the first patterns 505, the third patterns, the fourth capping layer pattern 540, the etch stop layer pattern 529 to fill the ninth openings 448, and planarizing an upper portion of the second conductive layer until the top surface of the fourth capping layer pattern 540 may be exposed. Upper portions of the planarized second conductive layer may serve as pad layer 590, and lower portions thereof may serve as the contact plug 580. That is, the contact plug 580 and the pad layer 590 may be formed to include substantially the same material by a single process, and thus may be formed in a self-aligned manner. In addition, the contact plug 580 and the pad layer 590 may not be formed by separate processes, which may reduce the etching process for formation of fine patterns. The second conductive layer may include a metal and/or polysilicon doped with impurities.

In example embodiments, a plurality of contact plugs 580 may be formed both in the first and second directions, each of which may be formed to contact the impurity region 303. In example embodiments, a top surface of the pad layers 590 may be substantially coplanar with those of the third patterns, the fourth capping layer patterns 540, the etch stop layer patterns 529.

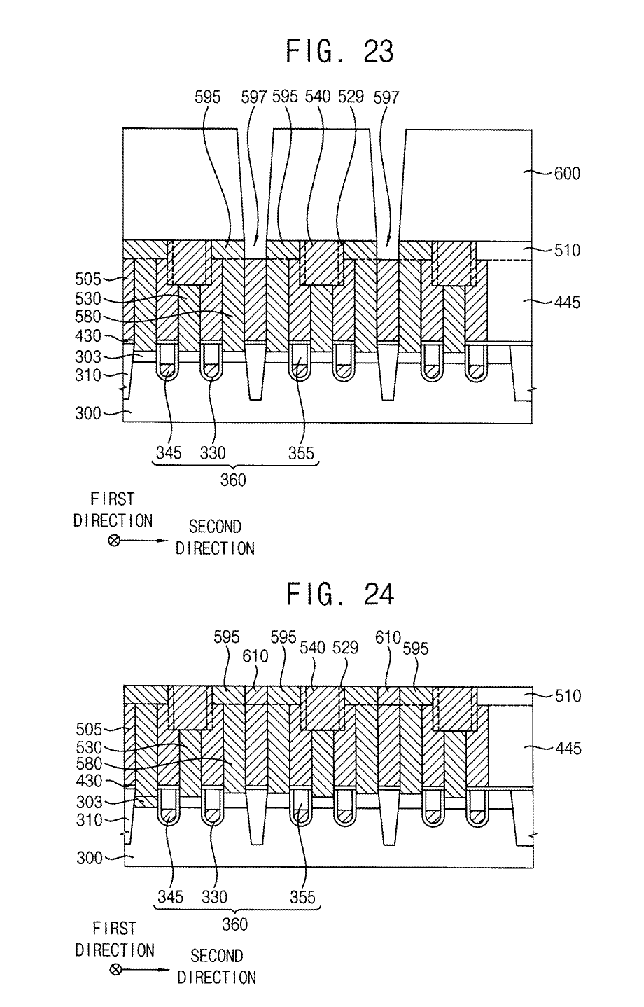

Referring to FIG. 23, a fourth mask 600 may be formed on the pad layers 590, the fourth capping layer patterns 540 and the etch stop layer patterns 529, and the pad layers 590 may be etched using the fourth mask 600 as an etching mask. Thus, the pads 595 separated by a tenth opening 597 may be formed.

In example embodiments, the fourth mask 600 may expose portions of the pad layer 590 on the first patterns 505. Thus, each pad layer 590 may be divided into two pads 595 by the etching process, and the tenth openings 597 may expose portions of a top surface of the first patterns 505. A width of each pad 595 in the second direction may be larger than the width of each contact plug 580.

Referring to FIG. 24, a division layer pattern 610 may be formed to fill each tenth opening 597.

The division layer pattern 610 may be formed by removing the fourth mask 600, forming an second insulating layer on the third patterns, the pads 595, the fourth capping layer patterns 540 and the etch stop layer patterns 529 to fill the tenth opening 597, and planarizing an upper portion of the second insulating layer until a top surface of the pads 595 may be exposed. The second insulating layer may be formed to include a nitride, e.g., silicon nitride.

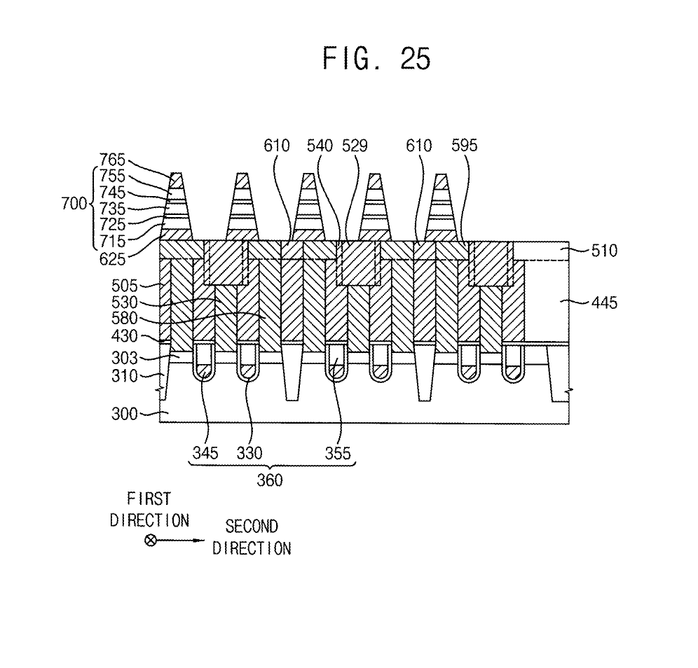

Referring to FIG. 25, a process substantially the same as or similar to that illustrated with reference to FIG. 4 may be performed. Thus, a lower electrode 625, an MTJ structure 700 and an upper electrode 765 sequentially stacked on each pad 595 may be formed to contact the top surface thereof. In an example embodiment, the MTJ structure 700 may be formed to include a fixed layer structure pattern 715, a first tunnel barrier layer pattern 725, a free layer pattern 735, a second tunnel barrier layer pattern 745 and a fifth capping layer pattern 755 sequentially stacked. The MTJ structure 700 may be electrically connected to each pad 595 through the lower electrode 625, and thus, may be electrically connected to the impurity region 303 of the substrate 300.

The lower electrode 625, the MTJ structure 700 and the upper electrode 765 may be formed by the following steps. A lower electrode layer, a fixed layer, a first tunnel barrier layer, a free layer, a second tunnel barrier layer, a fifth capping layer and an upper electrode layer may be sequentially formed on the pads 595, the division layer patterns 610, the fourth capping layer patterns 540 and the etch stop layer patterns 529. The upper electrode layer may be etched to form the upper electrode 765, and the fifth capping layer, the second tunnel barrier layer, the free layer, the first tunnel barrier layer, the fixed layer and the lower electrode layer may be sequentially patterned using the upper electrode 765 as an etching mask. Accordingly, a plurality of lower electrodes 625 and a plurality of MTJ structures 700 may be formed both in the first and second directions, and one lower electrode 625 and one MTJ structure 700 may be formed to overlap one pad 595.

The lower and upper electrodes 625 and 765 may be formed to include a conductive material such as, e.g., a metal such as W, Ti and Ta, and/or a metal nitride, e.g., WN, TiN, TaN, etc. In an example embodiment, the lower and upper electrodes 625 and 765 may be formed to include substantially the same material.

The fixed layer pattern 715 may be formed to include a ferromagnetic material, e.g., CoFeB, CoFe, NiFe, etc., and the fixed layer pattern 715 may contact a top surface of the lower electrode layer. The free layer pattern 735 may be formed to include a ferromagnetic material, e.g., CoFeB. The first and second tunnel barrier layer patterns 725 and 745 may be formed to include a metal oxide, e.g., magnesium oxide (MgO) or aluminum oxide (AlOx), a metal nitride, or metal an oxynitride.

The fifth capping layer pattern 755 may be formed to include a metal having an oxide layer formation energy lower than the oxide layer formation energy of Ta, e.g., magnesium (Mg), hafnium (Hf), aluminum (Al), Ti, beryllium (Be), terbium (Db), zirconium (Zr), etc. The fifth capping layer pattern 755 may be also formed to include a metal having a melting temperature that is higher than the melting temperature of Al, e.g., Ti, Mg, Hf, etc. In example embodiments, the capping layer 250 may be formed to include a metal having an oxide layer formation energy lower than the oxide layer formation energy of Ta and a melting temperature that is higher than the melting temperature of Al. A protection layer (not shown) may be formed on the capping layer 250, which may include a metal, e.g., Ta.

The MTJ structure 700 and the method of forming the MTJ structure 700 may not be limited to the above description, and various types of MTJ structures may be formed.

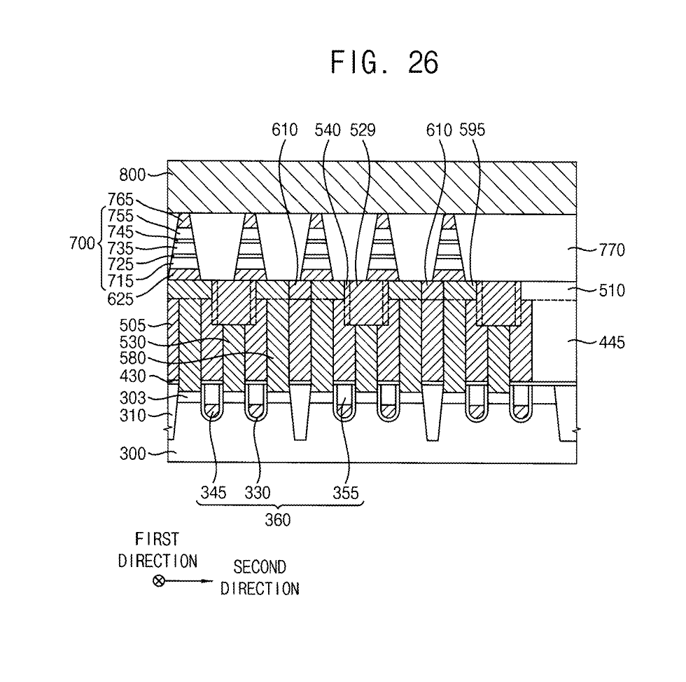

Referring to FIG. 26, a second insulating interlayer 770 covering the lower electrode 625, the MTJ structure 700 and the upper electrode 765 may be formed, an upper portion of the second insulating interlayer 770 may be planarized until a top surface of the upper electrode 765 may be exposed, and a bit line 800 may be formed on the second insulating interlayer 770 to contact the upper electrode 765.

The second insulating interlayer 770 may be formed to include an oxide, e.g., boro phospho silicate glass (BPSG), undoped silicate glass (USG) and spin on glass (SOG), etc.

The bit line 800 may be formed by forming a third conductive layer on the second insulating interlayer 770, and partially etching the third conductive layer. The third conductive layer may be formed to include a metal, a metal nitride and/or a metal silicide. In example embodiments, the bit line 800 may extend in the second direction, and a plurality of bit lines 800 may be formed in the first direction.

After forming the MTJ structure 700, the MTJ structure 700 may be exposed to a high temperature process. For example, an annealing process of the MTJ structure 700 may be performed at a high temperature of more than about 350° C., which may be performed to improve a crystal property of the free layer pattern 735 and/or to form a wiring (not shown) being electrically connected to the bit line 800 on the MTJ structure 700. In the annealing process, oxygen may be excessively generated from the second tunnel barrier layer pattern 745, and the excessive oxygen may be effectively absorbed into the fifth capping layer pattern 755. The excessive oxygen generated from the second tunnel barrier layer pattern 745 may not move toward an interface between the free layer pattern 735 and the first tunnel barrier layer pattern 725 so that a crystal property of the free layer pattern 735 may be substantially prevented from being deteriorated, and a TMR of the MTJ structure 700 may be maintained high.

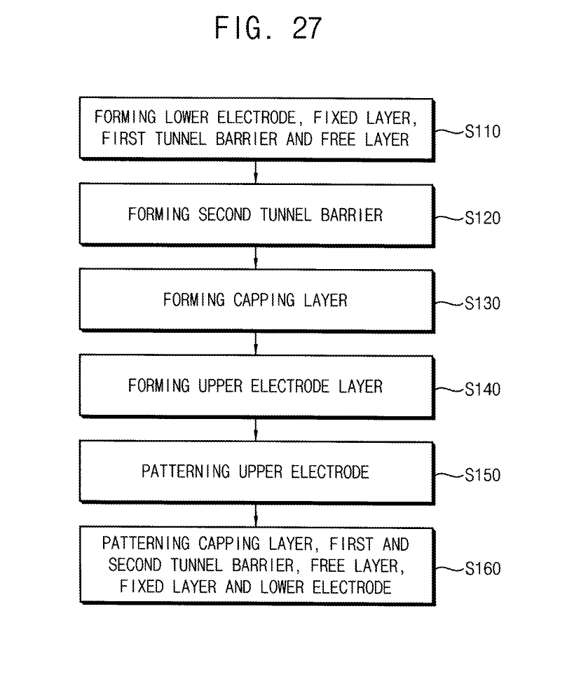

FIG. 27 is a flow chart illustrating a method of manufacturing an MRAM device in accordance with example embodiments. The method starts at S110, where a lower electrode layer, a fixed layer, a first tunnel barrier layer and a free layer are formed in sequence on a substrate. A second tunnel barrier layer is then formed on the free layer at S120, the second tunnel barrier layer including a metal oxide. At S130, a capping layer is formed on the second tunnel barrier layer, the capping layer having an oxide layer formation energy that is lower than an oxide layer formation energy of tantalum. When the capping layer is formed, an upper electrode layer is formed on the capping layer at S140, and the upper electrode layer is patterned at S150 to from an upper electrode. At S160, the capping layer, the second tunnel barrier layer, the free layer, the first tunnel barrier layer, the fixed layer and the lower electrode layer are patterned by using the upper electrode as an etching mask to form a capping layer pattern, a second tunnel barrier layer pattern, a free layer pattern, a first tunnel barrier layer pattern, a fixed layer pattern and a lower electrode, respectively.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive concept. Accordingly, all such modifications are intended to be included within the scope of the example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1-9. (canceled)

10. A method of manufacturing an MRAM device, the method comprising:
sequentially forming a lower electrode layer, a fixed layer, a first tunnel barrier layer and a free layer on a substrate;
forming a second tunnel barrier layer including a metal oxide on the free layer;
forming a capping layer including a metal having an oxide layer formation energy lower than an oxide layer formation energy of tantalum on the second tunnel barrier layer;
forming an upper electrode layer on the capping layer;
patterning the upper electrode layer to form a upper electrode; and
sequentially patterning the capping layer, the second tunnel barrier layer, the free layer, the first tunnel barrier layer, the fixed layer and the lower electrode layer using the upper electrode as an etching mask to form a capping layer pattern, a second tunnel barrier layer pattern, a free layer pattern, a first tunnel barrier layer pattern, a fixed layer pattern and a lower electrode, respectively.

11. The method of claim 10, wherein the capping layer pattern includes magnesium.

12. The method of claim 10, further comprising:
forming an upper electrode on the capping layer pattern; and
forming a wiring on the upper electrode at a temperature of more than about 350° C.

13. The method of claim 10, wherein the second tunnel barrier layer is formed using magnesium oxide.

14. The method of claim 13, wherein the first tunnel barrier layer is formed using magnesium oxide.

15. The method of claim 13, wherein the free layer pattern is formed using CoFeB.

16. A method of manufacturing an MRAM device, the method comprising:
forming a magnetic tunneling junction portion on a substrate;
forming a capping layer on the magnetic tunneling junction portion, the capping layer being configured to absorb oxygen generated from the magnetic tunneling junction portion;
forming an upper electrode on the capping layer; and
forming a wiring on the upper electrode.

17. The method of claim 16, wherein forming the magnetic tunneling junction portion comprises forming a lower electrode layer on the substrate, a fixed layer on the lower electrode, a first tunnel barrier layer on the fixed layer, a free layer on the first tunnel barrier layer and a second tunnel barrier layer on the free layer.

18. The method of claim 17, wherein the second tunnel barrier layer comprises a metal oxide.

19. The method of claim 16, wherein forming the upper electrode comprises:
forming an upper electrode layer on the capping layer; and
patterning the upper electrode layer.

20. The method of claim 16, wherein forming the wiring on the upper electrode is performed at a temperature of more than about 350° C.

21. The method of claim 17, further comprising forming a capping layer pattern, a second tunnel barrier layer pattern, a free layer pattern, a first tunnel barrier layer pattern, a fixed layer pattern and a lower electrode pattern by patterning the capping layer, the second tunnel barrier layer, the free layer, the first tunnel barrier layer, the fixed layer and the lower electrode layer, respectively, using the upper electrode as an etching mask.

22. The method of claim 16, wherein the capping layer comprises at least one of magnesium, hafnium, aluminum, titanium, beryllium, terbium and zirconium.

23. The method of claim 16, wherein the capping layer comprises a metal having a melting temperature that is higher than a melting temperature of aluminum.

24. The method of claim 17, wherein the capping layer comprises a metal having an oxide layer formation energy that is lower than an oxide layer formation energy of tantalum.

25. The method of claim 17, wherein the capping layer is configured to absorb oxygen generated from the second tunnel barrier layer.

26. The method of claim 16, wherein the capping layer is configured to absorb the oxygen when an annealing process is performed at a temperature of more than about 300° C.

27. The method of claim 17, wherein the first tunnel barrier layer comprises magnesium oxide.

28. The method of claim 17, wherein the second tunnel barrier layer comprises magnesium oxide.

29. The method of claim 17, wherein the free layer comprises CoFeB.
